(19) United States
(12) Patent Application Publication
(10) Pub. No.: US 2026/0239602 A1
(43) Pub. Date: Aug. 13, 2026

(54) SEMICONDUCTOR STRUCTURE INCLUDING AN ELECTRICAL PAD AND METHOD OF MANUFACTURING THE SAME

(71) Applicant: NANYA TECHNOLOGY CORPORATION, NEW TAIPEI CITY (TW)

(72) Inventor: SZU-YAO CHANG, NEW TAIPEI CITY (TW)

(21) Appl. No.: 19/050,858

(22) Filed: Feb. 11, 2025

(51) Int. Cl. H10B 12/00

(52) U.S. Cl. CPC H10B 12/33; H10B 12/488

(57) ABSTRACT

A semiconductor structure and a method of manufacturing a semiconductor structure are provided. The semiconductor structure includes a substrate, an upper structure, a vertical transistor and an electrical pad. The upper structure is disposed on the substrate. The vertical transistor is disposed in the upper structure. The electrical pad is disposed on the vertical transistor. A periphery portion of the electrical pad horizontally overlaps an upper portion of the vertical transistor.

### TECHNICAL FIELD

The present disclosure relates to a semiconductor structure and a method of manufacturing the same, and more particularly, to a semiconductor structure including an electrical pad, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical memory devices (such as dynamic random access memory (DRAM) devices) include signal lines, such as word lines and bit lines crossing the word lines. As DRAM devices are scaled down and the dimensions and/or pitches of the signal lines are getting smaller, the complicated manufacturing process and high manufacturing cost will be a critical concern.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor structure including a substrate, an upper structure, a vertical transistor and an electrical pad. The upper structure is disposed on the substrate. The vertical transistor is disposed in the upper structure. The electrical pad is disposed on the vertical transistor. A periphery portion of the electrical pad horizontally overlaps an upper portion of the vertical transistor.

Another aspect of the present disclosure provides a semiconductor structure including a substrate, an upper structure, a vertical transistor and an electrical pad. The substrate includes a capacitor. The upper structure is disposed on the substrate. The vertical transistor is disposed in the upper structure and electrically connected to the capacitor. The vertical transistor extends beyond a top portion of the upper structure. The electrical pad is disposed on the vertical transistor.

Another aspect of the present disclosure provides a method of manufacturing a semiconductor structure. The method includes providing a stacked structure including a substrate and an upper structure disposed on the substrate. The method also includes forming a hole to extend through the upper structure. The method also includes forming a vertical transistor in the hole, wherein an upper portion of the vertical transistor extends beyond the upper structure. The method also includes forming an electrical pad on the vertical transistor.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method of manufacturing a semiconductor structure in accordance with one embodiment of the present disclosure.

FIG. 2 illustrates a cross-sectional view of one or more stages of an example of a method of manufacturing a semiconductor structure in accordance with one embodiment of the present disclosure.

FIG. 3 illustrates a cross-sectional view of one or more stages of an example of a method of manufacturing a semiconductor structure in accordance with one embodiment of the present disclosure.

FIG. 4 illustrates a cross-sectional view of one or more stages of an example of a method of manufacturing a semiconductor structure in accordance with one embodiment of the present disclosure.

FIG. 5 illustrates a cross-sectional view of one or more stages of an example of a method of manufacturing a semiconductor structure in accordance with one embodiment of the present disclosure.

FIG. 6 illustrates a cross-sectional view of one or more stages of an example of a method of manufacturing a semiconductor structure in accordance with one embodiment of the present disclosure.

FIG. 7 illustrates a cross-sectional view of one or more stages of an example of a method of manufacturing a semiconductor structure in accordance with one embodiment of the present disclosure.

FIG. 8 illustrates a cross-sectional view of one or more stages of an example of a method of manufacturing a semiconductor structure in accordance with one embodiment of the present disclosure.

FIG. 9 illustrates a cross-sectional view of one or more stages of an example of a method of manufacturing a semiconductor structure in accordance with one embodiment of the present disclosure.

FIG. 10 illustrates a cross-sectional view of one or more stages of an example of a method of manufacturing a semiconductor structure in accordance with one embodiment of the present disclosure.

FIG. 11 illustrates an enlarged view of an area “A” of FIG. 10.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

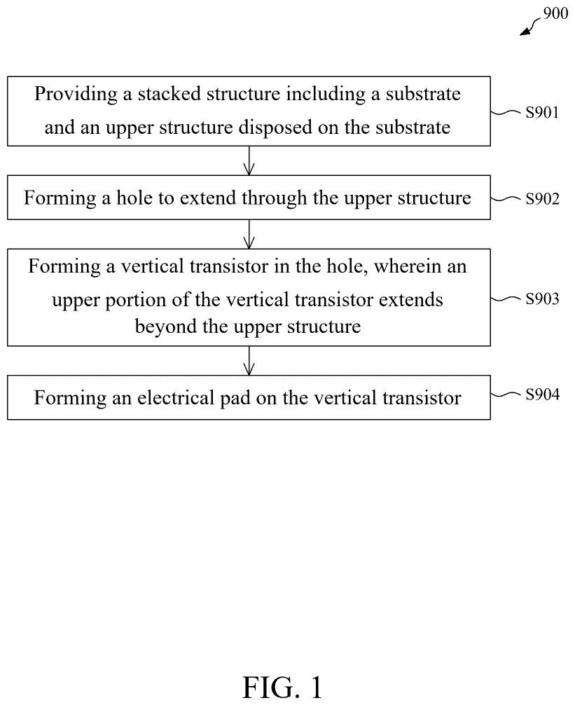

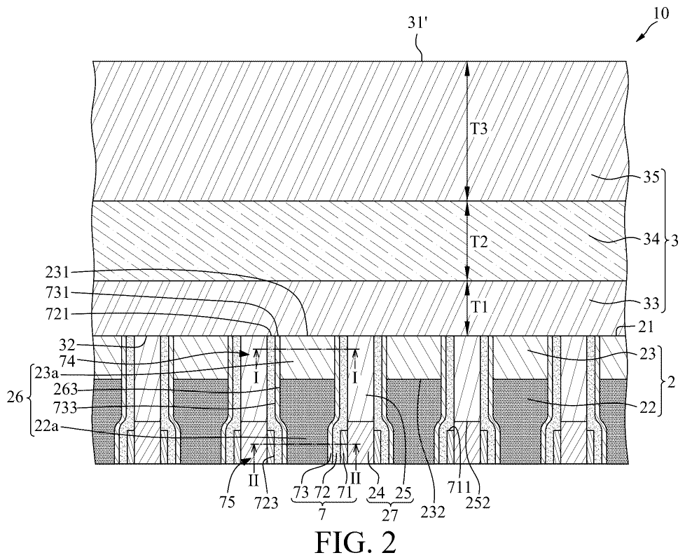

FIG. 1 illustrates, in a flowchart diagram form, a method 900 for manufacturing a semiconductor structure 1 in accordance with one embodiment of the present disclosure. FIG. 2 to FIG. 11 illustrate stages of a method for manufacturing a semiconductor structure 1 in accordance with one embodiment of the present disclosure. At least some of these figures have been simplified for a better understanding of the aspects of the present disclosure.

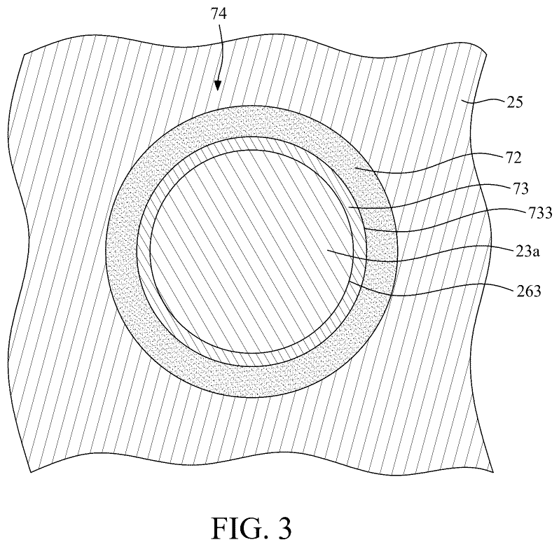

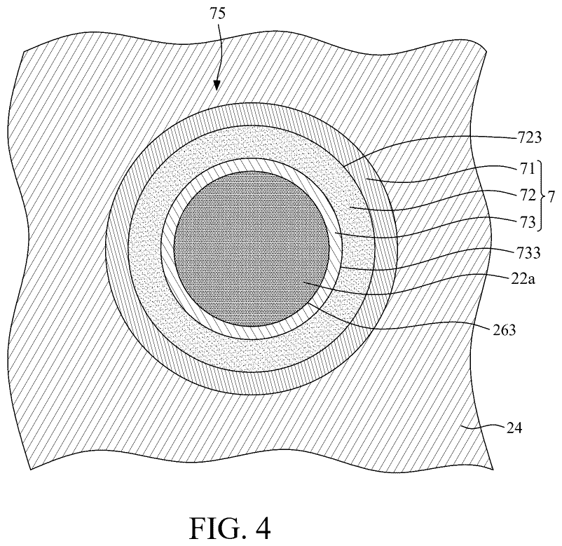

Referring to FIG. 2 to FIG. 4, at step S901, a stacked structure 10 may be provided. The stacked structure 10 may include a substrate 2 and an upper structure 3 disposed on the substrate 2. FIG. 2 is a schematic cross-sectional view of the stacked structure 10 in accordance with some embodiments of the present disclosure. FIG. 3 is a schematic cross-sectional view of an upper portion 74 of the capacitor 7 of the stacked structure 10 taken along line I-I of FIG. 2. FIG. 4 is a schematic cross-sectional view of a lower portion 75 of the capacitor 7 of the stacked structure 10 taken along line II-II of FIG. 2.

In some embodiments, the substrate 2 may have a top surface 21, and may include a base portion 22 and a conductive material 23 on the base portion 22. The base portion 22 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some other embodiments, the base portion 22 may include a semiconductor-on-insulator substrate, such as a silicon-on-insulator (SOI) substrate, a silicon germanium-on-insulator (SGOI) substrate, or a germanium-on-insulator (GOI) substrate.

Depending on the IC fabrication stage, the base portion 22 may include various material layers (e.g., dielectric layers, semiconductor layers, and/or conductive layers) configured to form IC features (e.g., doped regions, isolation features, gate features, source/drain features, interconnect features, other features, or combinations thereof).

In some embodiments, the conductive material 23 may include a suitable conductive material. For example, the conductive material 23 may include tungsten (W), copper (Cu), aluminum (Al), silver (Ag), an alloy thereof, or a combination thereof. In some embodiments, the conductive material 23 may include transparent conductive oxide (TCO) material, such as indium tin oxide (ITO) and zinc oxide (ZnO).

In some embodiments, the substrate 2 may further include at least one capacitor 7 disposed therein. The capacitor 7 may be embedded in the substrate 2. In some embodiments, the capacitor 7 may be a vertical ring structure and surrounds a central portion 26. The central portion 26 may be in a cylinder shape, and may include a base material 22a and a conductive material 23a. The base material 22a of the central portion 26 may be a portion of the base portion 22 of the substrate 2. The conductive material 23a of the central portion 26 may be disposed on the base material 22a. The conductive material 23a of the central portion 26 may be a portion of the conductive material 23 of the substrate 2.

The capacitor 7 may include a first electrode 71 (e.g., a bottom electrode), an intermediate layer 72 and a second electrode 73 (e.g., a top electrode). It is contemplated that the number of the capacitor 7 is not limited. There may be a plurality of capacitors 7 in the substrate 2. The substrate 2 may further include filling material 27 between the capacitors 7.

The second electrode 73 may be a conductive layer such as titanium nitride (TiN) layer. The second electrode 73 may be disposed on and surround the lateral surface 263 of the central portion 26. Thus, the second electrode 73 may be interposed between the central portion 26 and the intermediate layer 72. Further, the intermediate layer 72 may be a high-k dielectric layer such as zirconium oxide (ZrO₂) layer. The intermediate layer 72 may be disposed on and surround the lateral surface 733 of the second electrode 73. Thus, the intermediate layer 72 may be interposed between the second electrode 73 and the first electrode 71. Further, the first electrode 71 may be a conductive layer such as titanium nitride (TiN) layer. The first electrode 71 may be disposed on and surround the lateral surface 723 of the intermediate layer 72. Thus, the first electrode 71 may be interposed between the intermediate layer 72 and the filling material 27.

The filling material 27 may include a lower portion 24 and an upper portion 25 disposed on the lower portion 24. The lower portion 24 may be a dielectric material or an insulation material, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof. The upper portion 25 may be a dielectric material or an insulation material, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof. The material of the upper portion 25 may be the same as or different from the material of the lower portion 24.

In some embodiments, the conductive material 23a of the central portion 26 contacts the second electrode 73. As shown in FIG. 2, a top surface 231 of the conductive material 23a of the central portion 26 (or a top surface 231 of the conductive material 23 of the substrate 2), a top surface 731of the second electrode 73 and a top surface 721 of the intermediate layer 72 may be substantially coplanar with or aligned with each other. Thus, the top surface 21 of the substrate 2 may include the top surface 231 of the conductive material 23a of the central portion 26 (or the top surface 231 of the conductive material 23 of the substrate 2), the top surface 731of the second electrode 73 and the top surface 721 of the intermediate layer 72. In addition, the capacitor 7 may include an upper portion 74 and a lower portion 75 below the upper portion 74, and the upper portion 74 of the capacitor 7 may be exposed from the top surface 21 of the substrate 2.

Further, the first electrode 71 may be disposed below the conductive material 23a of the central portion 26 and below the upper portion 25 of the filling material 27. That is, an elevation of a top surface 711 of the first electrode 71 may be lower than an elevation of a bottom surface 232 of the conductive material 23a of the central portion 26 and below a bottom surface 252 of the upper portion 25 of the filling material 27. The upper portion 74 of the capacitor 7 may not include the first electrode 71. In some embodiments, only the lower portion 75 may be designated as a capacitor.

The upper structure 3 may be disposed on the top surface 21 of the substrate 2. The upper structure 3 may have a top surface 31′ and a bottom surface 32 opposite to the top surface 31′. The bottom surface 32 of the upper structure 3 may contact the top surface 21 of the substrate 2. The top surface 31′ of the upper structure 3 may be a substantially flat plane. The entire top surface 31′ of the upper structure 3 may be at a same elevation from a cross-sectional view.

The upper structure 3 may include a bottom insulation layer 33, a conductive layer 34 and a top insulation layer 35. The bottom insulation layer 33 may be disposed on the top surface 21 of the substrate 2. In some embodiments, the bottom insulation layer 33 may include a dielectric material or an insulation material, such as nitride, oxide, oxynitride amorphous silicon, polycrystalline silicon, or other suitable material. The bottom insulation layer 33 may have a thickness T1.

The conductive layer 34 may be disposed on the bottom insulation layer 33. In some embodiments, the conductive layer 34 may include a suitable conductive material such as tungsten (W), copper (Cu), aluminum (Al), silver (Ag), an alloy thereof, or a combination thereof. In some embodiments, the conductive layer 34 may include signal lines, such as word lines. The conductive layer 34 may have a thickness T2.

The top insulation layer 35 may be disposed on the conductive layer 34 (e.g. the word line). In some embodiments, the top insulation layer 35 may include a dielectric material or an insulation material, such as nitride, oxide, oxynitride amorphous silicon, polycrystalline silicon, or other suitable material. The material of the top insulation layer 35 may be the same as or different from the material of the bottom insulation layer 33. The top insulation layer 35 may have a consistent thickness T3. In some embodiments, the thickness T3 of the top insulation layer 35 may be 70 nm.

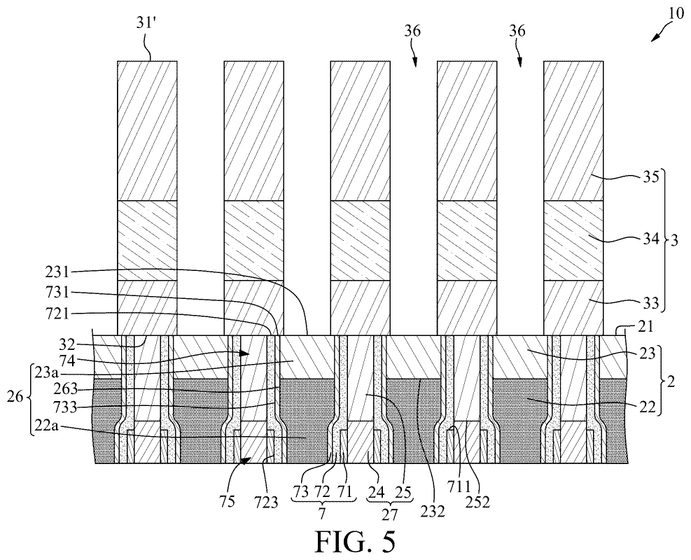

Referring to FIG. 5, at step S902, at least one hole 36 may be formed to extend through the upper structure 3 by, for example, dry etching. Thus, the hole 36 may extend between the top surface 31′ of the upper structure 3 and the bottom surface 32 of the upper structure 3, and may extend through the bottom insulation layer 33, the conductive layer 34 (e.g. the word line) and the top insulation layer 35. The hole 36 may be located right above the conductive material 23a of the central portion 26. Thus, the top surface 231 of the conductive material 23a of the central portion 26 (or a top surface 231 of the conductive material 23 of the substrate 2) may be exposed from the hole 36. The hole 36 may be stopped by the conductive material 23a of the central portion 26. A width of the hole 36 may be less than a width of the conductive material 23a of the central portion 26. A central axis of the hole 36 may be aligned with a central axis of the conductive material 23a of the central portion 26. Thus, a portion of the top surface 231 of the conductive material 23a of the central portion 26 (or a top surface 231 of the conductive material 23 of the substrate 2) may be a bottom wall of the hole 36.

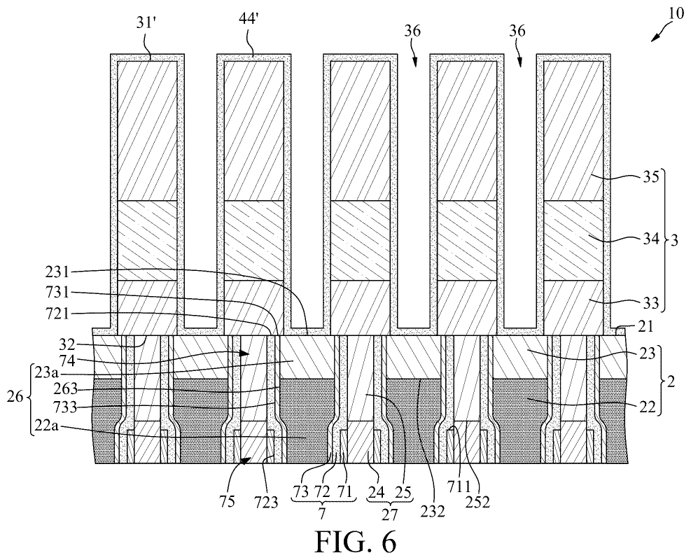

Referring to FIG. 6 to FIG. 8, at step S903, at least one vertical transistor 4 may be formed in the hole 36, and an upper portion 45 of the vertical transistor 4 may extend beyond the upper structure 3.

Referring to FIG. 6, an insulation layer 44′ may be formed on the top surface 31′ of the upper structure 3 and in the hole 36 by, for example, deposition. The insulation layer 44′ may include an insulation material or dielectric material such as gate oxide (GOX).

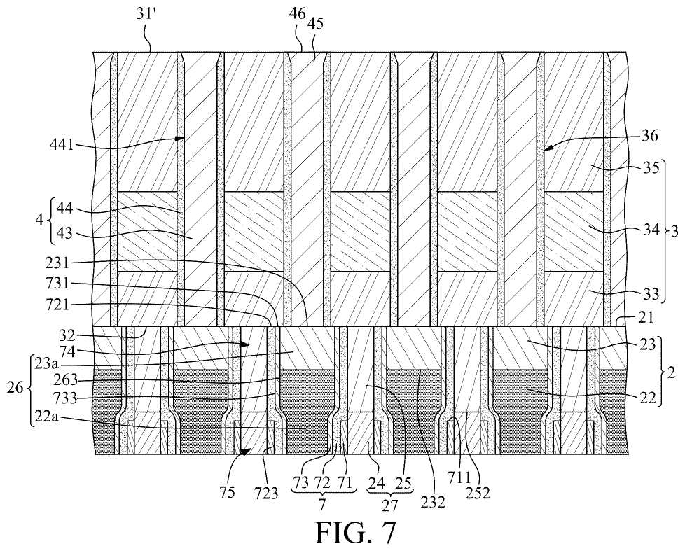

Referring to FIG. 7, the portion of the insulation layer 44′ on the top surface 31′ of the upper structure 3 and on the bottom wall of the hole 36 are removed so as to become to a periphery insulation layer 44 on the sidewall of the hole 36. Then, a main material 43 may be formed in the central hole 441 defined by the periphery insulation layer 44. The main material 43 may include a conductive material such as indium-gallium-zinc oxide (IGZO). Meanwhile, a vertical transistor 4 (including the main material 43 and the periphery insulation layer 44) may be formed in the hole 36.

The vertical transistor 4 may be disposed in the hole 36 and on the substrate 2. Thus, the vertical transistor 4 may extend through the bottom insulation layer 33, the conductive layer 34 and the top insulation layer 35. Further, a vertical projection of the vertical transistor 4 may be within the central portion 26. As shown in FIG. 7, the vertical transistor 4 may include a main material 43 and a periphery insulation layer 44. The main material 43 may be a conductive material such as indium-gallium-zinc oxide (IGZO). A bottom end of the main material 43 may contact the conductive material 23a of the central portion 26. Thus, the vertical transistor 4 may be electrically connected to the capacitor 7 through the conductive material 23a of the central portion 26 surrounded by the second electrode 73 of the capacitor 7.

The vertical transistor 4 may include an upper portion 45 adjacent to the top surface 31′ of the top insulation layer 35. The vertical transistor 4 may have a top surface 46 substantially coplanar with or aligned with the top surface 31′ of the top insulation layer 35.

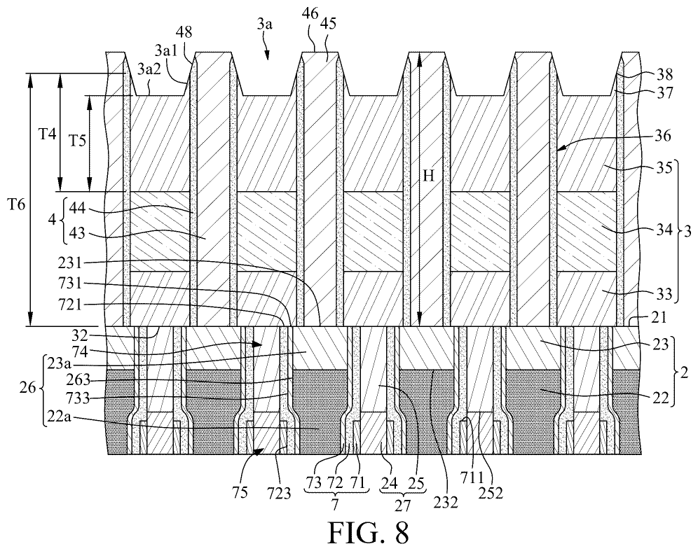

Referring to FIG. 8, a portion of the top insulation layer 35 of the upper structure 3 around the upper portion 45 of the vertical transistor 4 may be removed by, for example, etching, so to define at least one first recess 3a around the vertical transistors 4. Thus, the vertical transistor 4 may extend beyond the top insulation layer 35 of the upper structure 3.

The first recess 3a may be formed or disposed between two vertical transistors 4. The first recess 3a may taper toward the substrate 2. The first recess 3a may be recessed from the top surface 46 of the vertical transistor 4 and the top surface 31′ of the top insulation layer 35. For example, the first recess 3a may be recessed from a top portion 38 of the upper structure 3. The first recess 3a may have an inner surface 3a1 and a bottom surface 3a2. The inner surface 3a1 of the first recess 3a may be substantially coplanar with or aligned with a slanted surface 48 of the vertical transistor 4. The upper portion 45 of the vertical transistor 4 may protrude from the bottom surface 3a2 of the top insulation layer 35 of the upper structure 3. The top portion of the upper portion 45 of the vertical transistor 4 may taper away from the substrate 2.

Meanwhile, the top insulation layer 35 of the upper structure 3 may include a protrusion portion 37. The protrusion portion 37 may define the first recess 3a. The protrusion portion 37 may taper away from the substrate 2. The protrusion portion 37 may contact the vertical transistor 4. For example, the protrusion portion 37 may be defined by the inner surface 3a1 of the first recess 3a and a lateral surface of the vertical transistor 4. The protrusion portion 37 may protrude from the bottom surface 3a2 of the first recess 3a. The protrusion portion 37 may include the top portion 38. The top portion 38 may contact the vertical transistor 4.

Meanwhile, the top insulation layer 35 of the upper structure 3 may have a first thickness T4 and a second thickness T5. The first thickness T4 may be a vertical distance between the top portion 38 and a top surface of the conductive layer 34. The second thickness T5 may be a vertical distance between the bottom surface 3a2 of the first recess 3a and the top surface of the conductive layer 34. The first thickness T4 is greater than the second thickness T5.

The upper structure 3 may have a maximum thickness T6 that is defined as a vertical distance between the bottom surface 32 of the upper structure 3 and the top portion 38 of the upper structure 3. The maximum thickness T6 of the upper structure 3 is a sum of the thickness T1 of the bottom insulation layer 33, the thickness T2 of the conductive layer 34 and the first thickness T4 of the top insulation layer 35. The vertical transistor 4 may have a height H. The height H of the vertical transistor 4 may be greater than the maximum thickness T6 of the upper structure 3. Thus, the upper portion 45 of the vertical transistor 4 may extend beyond the top portion 38 of the upper structure 3.

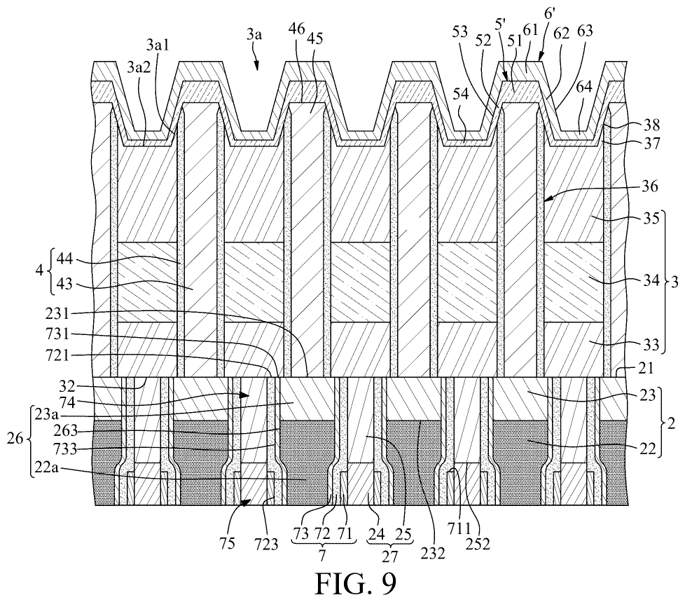

Referring to FIG. 9 to FIG. 11, at step S903, an electrical pad 6 may be formed or disposed on the vertical transistor 4.

Referring to FIG. 9, a first conductive layer 5′ may be formed or disposed on the vertical transistor 4 and in the first recess 3a by, for example, physical vapor deposition (PVD). The first conductive layer 5′ may include transparent conductive oxide (TCO) material, such as indium tin oxide (ITO) and zinc oxide (ZnO). The first conductive layer 5′ may include a main portion 51, a periphery portion 52 and a bottom portion 54 formed concurrently.

The main portion 51 may be disposed on the upper portion 45 of the vertical transistor 4, and may contact the top surface 46 of the vertical transistor 4. The main portion 51 may be electrically connected to the vertical transistor 4. A thickness of the main portion 51 may be 5 nm. The periphery portion 52 may be disposed on the inner surface 3a1 of the first recess 3a, and may extend between the main portion 51 and the bottom portion 54. The periphery portion 52 may have a lateral surface 53. A thickness of the periphery portion 52 may be 1 nm to 2 nm. Thus, the thickness of the periphery portion 52 may be less than the thickness of the main portion 51.

The bottom portion 54 may be disposed on the bottom surface 3a2 of the first recess 3a. A thickness of the bottom portion 54 may be 1 nm to 2 nm. Thus, the thickness of the bottom portion 54 may be equal to the thickness of the periphery portion 52, and may be less than the thickness of the main portion 51. The first conductive layer 5′ may be substantially conformal with the first recess 3a and the protruded upper portion 45 of the vertical transistor 4.

Then, a second conductive layer 6′ may be formed or disposed on the first conductive layer 5′ (e.g., on the vertical transistor 4) and in the first recess 3a by, for example, physical vapor deposition (PVD). The second conductive layer 6′ may include a suitable conductive material such as tungsten (W), copper (Cu), aluminum (Al), silver (Ag), an alloy thereof, or a combination thereof. The second conductive layer 6′ may include a main portion 61, a periphery portion 62 and a bottom portion 64 formed concurrently.

The main portion 61 may be disposed on or disposed over the upper portion 45 of the vertical transistor 4, and may contact the main portion 51 of the first conductive layer 5′. The main portion 61 of the second conductive layer 6′ may be electrically connected to the vertical transistor 4 through the main portion 51 of the first conductive layer 5′. A thickness of the main portion 61 may be 50 nm. The periphery portion 62 may be disposed on the periphery portion 52 of the first conductive layer 5′ (e.g., on the inner surface 3a1 of the first recess 3a), and may extend between the main portion 61 and the bottom portion 64. The periphery portion 62 may have a lateral surface 63. A thickness of the periphery portion 62 may be 20 nm to 30 nm. Thus, the thickness of the periphery portion 62 may be less than the thickness of the main portion 61.

The bottom portion 64 may be disposed on the bottom portion 54 of the first conductive layer 5′ (e.g., on the bottom surface 3a2 of the first recess 3a). A thickness of the bottom portion 64 may be 20 nm to 30 nm. Thus, the thickness of the bottom portion 64 may be equal to the thickness of the periphery portion 62, and may be less than the thickness of the main portion 61. The second conductive layer 6′ may be substantially conformal with the first conductive layer 5′. Thus, the second conductive layer 6′ may be substantially conformal with the first recess 3a and the protruded upper portion 45 of the vertical transistor 4.

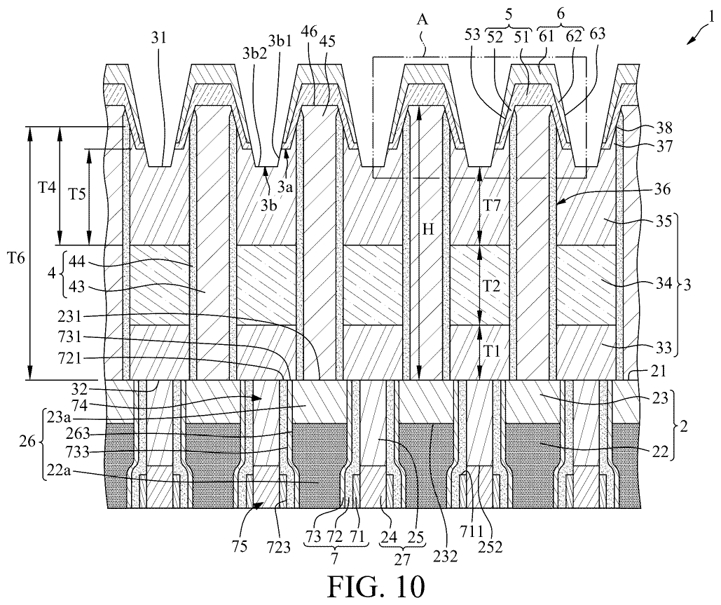

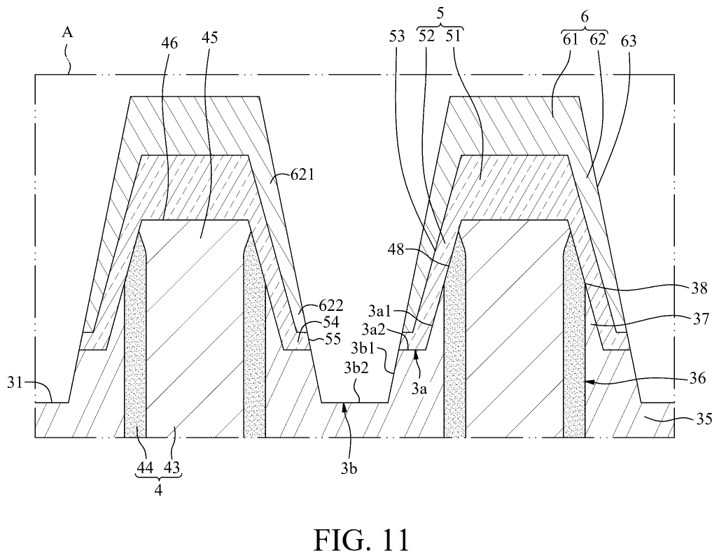

Referring to FIG. 10 and FIG. 11, wherein FIG. 11 illustrates an enlarged view of an area “A” of FIG. 10, a removing process may be conducted. At least a portion of the bottom portion 54 of the first conductive layer 5′ and at least a portion of the bottom portion 64 of the second conductive layer 6′ that are disposed in the first recess 3a may be removed by, for example, etching, so as to cut off the first conductive layer 5′ and the second conductive layer 6′, and form a conductive structure 5 on the vertical transistor 4 and an electrical pad 6 on the conductive structure 5 and on the vertical transistor 4. That is, the first conductive layer 5′ and the second conductive layer 6′ may be patterned. The adjacent two conductive structures 5 may be not electrically connected to each other. The adjacent two electrical pads 6 may be not electrically connected to each other.

In addition, a portion of the top insulation layer 35 of the upper structure 3 around the upper portion 45 of the vertical transistor 4 may be removed by, for example, etching, so to define at least one second recess 3b around the vertical transistors 4. The second recess 3b may be disposed between two vertical transistors 4. The second recess 3b may taper toward the substrate 2. The second recess 3b may be recessed from the bottom surface 3a2 of the first recess 3a. The second recess 3b may have an inner surface 3b1 and a bottom surface 3b2. The inner surface 3b1 of the second recess 3b may be substantially continuous with and aligned with a lateral surface 63 of a periphery portion 62 of the electrical pad 6 and a lateral surface 55 of the remaining bottom portion 54 of the conductive structure 5.

Meanwhile, the bottom surface 3b2 of the second recess 3b may be an upper surface 31 of the upper structure 3. The top insulation layer 35 of the upper structure 3 may have a third thickness T7. The third thickness T7 may be a vertical distance between the bottom surface 3b2 of the second recess 3b and the top surface of the conductive layer 34. The third thickness T7 may be less than the first thickness T4 and the second thickness T5. In some embodiments, the third thickness T7 of the top insulation layer 35 may be 35 nm, 40 nm, 45 nm, 50 nm, 55 nm or 60 nm.

The conductive structure 5 may be disposed between the vertical transistor 4 and the electrical pad 6. The conductive structure 5 may be in a substantially inverted “U” shape in a cross section. The conductive structure 5 may include a cap structure in the cross section. The conductive structure 5 may include a main portion 51 and a periphery portion 52. The main portion 51 may be disposed on the vertical transistor 4. The main portion 51 may taper away from the substrate 2.

The periphery portion 52 may extend downward from the main portion 51, and may have a lateral surface 53. The periphery portion 52 may have a consistent thickness. Thus, the lateral surface 53 of the periphery portion 52 may be non-parallel with a lateral surface 63 of the periphery portion 62 of the electrical pad 6. In some embodiments, the periphery portion 52 of the conductive structure 5 may taper toward the substrate 2. The periphery portion 52 of the conductive structure 5 may horizontally overlap the upper portion 45 of the vertical transistor 4 and the periphery portion 62 of the electrical pad 6. In some embodiments, the conductive structure 5 may be omitted.

The electrical pad 6 may be also referred to as “a landing pad”. The electrical pad 6 may be disposed on or disposed over the conductive structure 5 (e.g., on the vertical transistor 4). The electrical pad 6 may be in a substantially inverted “U” shape in a cross section. The electrical pad 6 may include a cap structure in the cross section. The electrical pad 6 may include a main portion 61 and a periphery portion 62. The main portion 61 may be disposed on the main portion 51 of the conductive structure 5. The main portion 61 may taper away from the substrate 2.

The periphery portion 62 may extend downward from the main portion 61, and may have a lateral surface 63. The periphery portion 62 of the electrical pad 6 may taper toward the substrate 2. Thus, a thickness of an upper portion 621 of the periphery portion 62 may be greater than a thickness of a lower portion 622 of the periphery portion 62. In some embodiments, the periphery portion 62 may have a consistent thickness. The periphery portion 62 of the electrical pad 6 may horizontally overlap the upper portion 45 of the vertical transistor 4, the periphery portion 52 of the conductive structure 5 and the top portion 38 of the upper structure 3. The periphery portion 52 of the conductive structure 5 may be disposed between the slanted surface 48 of the vertical transistor 4 (or a lateral surface of the vertical transistor 4) and the periphery portion 62 of the electrical pad 6.

Meanwhile, a semiconductor structure 1 may be formed.

In the embodiment illustrated in FIG. 2 to FIG. 11, during a manufacturing process, the first recess 3a may be formed between two adjacent vertical transistors 4. The upper portions 45 of the two adjacent vertical transistors 4 may be exposed in the first recess 3a. Thus, the first recess 3a may have a function of self-alignment. The upper portion 45 of the vertical transistor 4 may protrude from the upper structure 3. Thus, the electrical pad 6 (e.g., the landing pad) may be formed right over the vertical transistor 4 directly. In a comparative embodiment, a landing pad structure is formed by two times of self-align double patterning (SADP), which results in complicated manufacturing process and high manufacturing cost. In comparison, the manufacturing process of the semiconductor structure 1 of the embodiment illustrated in FIG. 2 to FIG. 11 is simplified, which results in a lower manufacturing cost.

FIG. 10 is a schematic cross-sectional view of a semiconductor structure 1 in accordance with some embodiments of the present disclosure. FIG. 11 illustrates an enlarged view of an area “A” of FIG. 10. In some embodiments, the semiconductor structure 1 may be a semiconductor device that includes a circuit, such as a memory cell. In some embodiments, the memory cell may include a dynamic random access memory cell (DRAM cell).

In addition, the semiconductor structure 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The semiconductor structure 1 may include a substrate 2 (e.g., a semiconductor substrate), an upper structure 3, a vertical transistor 4, a conductive structure 5 and an electrical pad 6.

The substrate 2 of FIG. 1 may be same as or similar to the substrate 2 of FIG. 2. In some embodiments, the substrate 2 may have a top surface 21, and may include a base portion 22, a conductive material 23 on the base portion 22 and at least one capacitor 7. The capacitor 7 may be embedded in the substrate 2. In some embodiments, the capacitor 7 may be a vertical ring structure and surrounds a central portion 26. The central portion 26 may be in a cylinder shape, and may include a base material 22a and a conductive material 23a. The base material 22a of the central portion 26 may be a portion of the base portion 22 of the substrate 2. The conductive material 23a of the central portion 26 may be a portion of the conductive material 23 of the substrate 2.

The capacitor 7 of FIG. 10 may be same as or similar to the capacitor 7 of FIG. 2, and may include a first electrode 71 (e.g., a bottom electrode), an intermediate layer 72 and a second electrode 73 (e.g., a top electrode). It is contemplated that the number of the capacitor 7 is not limited. There may be a plurality of capacitors 7 in the substrate 2. The substrate 2 may further include filling material 27 between the capacitors 7. The filling material 27 may include a lower portion 24 and an upper portion 25 disposed on the lower portion 24.

In some embodiments, the conductive material 23a of the central portion 26 contacts the second electrode 73. As shown in FIG. 10, the top surface 21 of the substrate 2 may include the top surface 231 of the conductive material 23a of the central portion 26 (or the top surface 231 of the conductive material 23 of the substrate 2), the top surface 731 of the second electrode 73 and the top surface 721 of the intermediate layer 72. In addition, the capacitor 7 may include an upper portion 74 and a lower portion 75 below the upper portion 74, and the upper portion 74 of the capacitor 7 may be exposed from the top surface 21 of the substrate 2. In some embodiments, only the lower portion 75 may be designated as a capacitor.

The upper structure 3 of FIG. 10 may be the same as or similar to the upper structure 3 of FIG. 2, and may include a bottom insulation layer 33, a conductive layer 34 and a top insulation layer 35. The bottom insulation layer 33 may be disposed on the top surface 21 of the substrate 2. The conductive layer 34 may be disposed on the bottom insulation layer 33. In some embodiments, the conductive layer 34 may include signal lines, such as word lines. The top insulation layer 35 may be disposed on the conductive layer 34 (e.g. the word line).

The upper structure 3 of FIG. 10 may define at least one hole 36 to extend through the upper structure 3. Thus, the hole 36 may extend through the bottom insulation layer 33, the conductive layer 34 (e.g. the word line) and the top insulation layer 35. The hole 36 may be located right above the conductive material 23a of the central portion 26. Thus, the top surface 231 of the conductive material 23a of the central portion 26 (or a top surface 231 of the conductive material 23 of the substrate 2) may be exposed from the hole 36. A width of the hole 36 may be less than a width of the conductive material 23a of the central portion 26.

The vertical transistor 4 may be formed or disposed in the hole 36. The vertical transistor 4 may include a main material 43 and a periphery insulation layer 44. The periphery insulation layer 44 may be formed or disposed on the sidewall of the hole 36. The main material 43 may be formed or disposed in the central hole 441 defined by the periphery insulation layer 44. The main material 43 may include a conductive material such as indium-gallium-zinc oxide (IGZO).

The vertical transistor 4 may include an upper portion 45 adjacent to the upper surface 31 of the top insulation layer 35. The vertical transistor 4 may have a top surface 46. The top insulation layer 35 of the upper structure 3 may define at least one first recess 3a around the vertical transistor 4. Thus, the vertical transistor 4 may extend beyond the top insulation layer 35 of the upper structure 3.

The first recess 3a may be formed or disposed between two vertical transistors 4. The first recess 3a may taper toward the substrate 2. The first recess 3a may be recessed from the top surface 46 of the vertical transistor 4. For example, the first recess 3a may be recessed from a top portion 38 of the upper structure 3. The first recess 3a may have an inner surface 3a1 and a bottom surface 3a2. The inner surface 3a1 of the first recess 3a may be substantially coplanar with or aligned with a slanted surface 48 of the vertical transistor 4. The upper portion 45 of the vertical transistor 4 may protrude from the bottom surface 3a2 of the top insulation layer 35 of the upper structure 3. The top portion of the upper portion 45 of the vertical transistor 4 may taper away from the substrate 2.

The top insulation layer 35 of the upper structure 3 may include a protrusion portion 37. The protrusion portion 37 may define the first recess 3a. The protrusion portion 37 may taper away from the substrate 2. The protrusion portion 37 may contact the vertical transistor 4. For example, the protrusion portion 37 may be defined by the inner surface 3a1 of the first recess 3a and a lateral surface of the vertical transistor 4. The protrusion portion 37 may protrude from the bottom surface 3a2 of the first recess 3a. The protrusion portion 37 may include the top portion 38. The top portion 38 may contact the vertical transistor 4.

The top insulation layer 35 of the upper structure 3 may further define at least one second recess 3b around the vertical transistors 4. The second recess 3b may be disposed between two vertical transistors 4. The second recess 3b may taper toward the substrate 2. The second recess 3b may be recessed from the bottom surface 3a2 of the first recess 3a. The second recess 3b may have an inner surface 3b1 and a bottom surface 3b2. The inner surface 3b1 of the second recess 3b may be substantially continuous with and aligned with a lateral surface 63 of a periphery portion 62 of the electrical pad 6 and a lateral surface 55 of the remaining bottom portion 54 of the conductive structure 5.

The bottom surface 3b2 of the second recess 3b may be the upper surface 31 of the upper structure 3.

The top insulation layer 35 of the upper structure 3 may have a first thickness T4, a second thickness T5 and a third thickness T7. The first thickness T4 may be a vertical distance between the top portion 38 and a top surface of the conductive layer 34. The second thickness T5 may be a vertical distance between the bottom surface 3a2 of the first recess 3a and the top surface of the conductive layer 34. The third thickness T7 may be a vertical distance between the bottom surface 3b2 of the second recess 3b and the top surface of the conductive layer 34. The first thickness T4 may be greater than the second thickness T5. The third thickness T7 may be less than the first thickness T4 and the second thickness T5. In some embodiments, the third thickness T7 of the top insulation layer 35 may be 35 nm, 40 nm, 45 nm, 50 nm, 55 nm or 60 nm.

The upper structure 3 may have a maximum thickness T6 that is defined as a vertical distance between the bottom surface 32 of the upper structure 3 and the top portion 38 of the upper structure 3. The maximum thickness T6 of the upper structure 3 is a sum of the thickness T1 of the bottom insulation layer 33, the thickness T2 of the conductive layer 34 and the first thickness T4 of the top insulation layer 35. The vertical transistor 4 may have a height H. The height H of the vertical transistor 4 may be greater than the maximum thickness T6 of the upper structure 3. Thus, the upper portion 45 of the vertical transistor 4 may extend beyond the top portion 38 of the upper structure 3.

The conductive structure 5 may be disposed between the vertical transistor 4 and the electrical pad 6. The conductive structure 5 may be in a substantially inverted “U” shape in a cross section. The conductive structure 5 may include a cap structure in the cross section. The conductive structure 5 may include a main portion 51 and a periphery portion 52. The main portion 51 may be disposed on the vertical transistor 4. The main portion 51 may taper away from the substrate 2.

The periphery portion 52 may extend downward from the main portion 51, and may have a lateral surface 53. The periphery portion 52 may have a consistent thickness. Thus, the lateral surface 53 of the periphery portion 52 may be non-parallel with a lateral surface 63 of the periphery portion 62 of the electrical pad 6. In some embodiments, the periphery portion 52 of the conductive structure 5 may taper toward the substrate 2. The periphery portion 52 of the conductive structure 5 may horizontally overlap the upper portion 45 of the vertical transistor 4 and the periphery portion 62 of the electrical pad 6. In some embodiments, the conductive structure 5 may be omitted.

The electrical pad 6 may be also referred to as “a landing pad”. The electrical pad 6 may be disposed on or disposed over the conductive structure 5 (e.g., on the vertical transistor 4). The electrical pad 6 may be in a substantially inverted “U” shape in a cross section. The electrical pad 6 may include a cap structure in the cross section. The electrical pad 6 may include a main portion 61 and a periphery portion 62. The main portion 61 may be disposed on the main portion 51 of the conductive structure 5. The main portion 61 may taper away from the substrate 2.

The periphery portion 62 may extend downward from the main portion 61, and may have a lateral surface 63. The periphery portion 62 of the electrical pad 6 may taper toward the substrate 2. Thus, a thickness of an upper portion 621 of the periphery portion 62 may be greater than a thickness of a lower portion 622 of the periphery portion 62. In some embodiments, the periphery portion 62 may have a consistent thickness. The periphery portion 62 of the electrical pad 6 may horizontally overlap the upper portion 45 of the vertical transistor 4, the periphery portion 52 of the conductive structure 5 and the top portion 38 of the upper structure 3. The periphery portion 52 of the conductive structure 5 may be disposed between the slanted surface 48 of the vertical transistor 4 (or a lateral surface of the vertical transistor 4) and the periphery portion 62 of the electrical pad 6.

One aspect of the present disclosure provides a semiconductor structure including a substrate, an upper structure, a vertical transistor and an electrical pad. The upper structure is disposed on the substrate. The vertical transistor is disposed in the upper structure. The electrical pad is disposed on the vertical transistor. A periphery portion of the electrical pad horizontally overlaps an upper portion of the vertical transistor.

Another aspect of the present disclosure provides a semiconductor structure including a substrate, an upper structure, a vertical transistor and an electrical pad. The substrate includes a capacitor. The upper structure is disposed on the substrate. The vertical transistor is disposed in the upper structure and electrically connected to the capacitor. The vertical transistor extends beyond a top portion of the upper structure. The electrical pad is disposed on the vertical transistor.

Another aspect of the present disclosure provides a method of manufacturing a semiconductor structure. The method includes providing a stacked structure including a substrate and an upper structure disposed on the substrate. The method also includes forming a hole to extend through the upper structure. The method also includes forming a vertical transistor in the hole, wherein an upper portion of the vertical transistor extends beyond the upper structure. The method also includes forming an electrical pad on the vertical transistor.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor structure, comprising:
a substrate;
an upper structure disposed on the substrate;
a vertical transistor disposed in the upper structure; and
an electrical pad disposed on the vertical transistor, wherein a periphery portion of the electrical pad horizontally overlaps an upper portion of the vertical transistor.

2. The semiconductor structure of claim 1, wherein the substrate includes a capacitor disposed therein.

3. The semiconductor structure of claim 2, wherein the capacitor is a ring structure and surrounds a central portion, and the central portion includes a base material and a conductive material disposed on the base material and electrically connected to the vertical transistor.

4. The semiconductor structure of claim 3, wherein the capacitor includes a first electrode, an intermediate layer and a second electrode, the second electrode is disposed on a lateral surface of the central portion, the intermediate layer is disposed on a lateral surface of the second electrode, and the first electrode is disposed on the lateral surface of the intermediate layer.

5. The semiconductor structure of claim 4, wherein the conductive material of the central portion contacts the second electrode.

6. The semiconductor structure of claim 5, wherein a top surface of the conductive material of the central portion, a top surface of the second electrode and a top surface of the intermediate layer are substantially coplanar with each other.

7. The semiconductor structure of claim 4, wherein the first electrode is disposed below the conductive material of the central portion.

8. The semiconductor structure of claim 3, wherein a vertical projection of the vertical transistor is within the central portion.

9. The semiconductor structure of claim 1, wherein the upper structure includes a bottom insulation layer disposed on the substrate, a conductive layer disposed on the bottom insulation layer and a top insulation layer disposed on the conductive layer.

10. The semiconductor structure of claim 1, the vertical transistor extends beyond the upper structure.

11. The semiconductor structure of claim 1, wherein in a cross section, the electrical pad is in a substantially inverted “U” shape.

12. The semiconductor structure of claim 11, wherein the electrical pad further include a main portion disposed over the vertical transistor, wherein the periphery portion of the electrical pad extends from the main portion of the electrical pad.

13. The semiconductor structure of claim 1, wherein the periphery portion of the electrical pad tapers toward the substrate.

14. The semiconductor structure of claim 1, wherein the upper structure includes a top portion contacting the vertical transistor, wherein the vertical transistor extends beyond the top portion of the upper structure.

15. The semiconductor structure of claim 1, wherein a height of the vertical transistor is greater than a maximum thickness of the upper structure.

16. The semiconductor structure of claim 1, wherein the upper structure defines a first recess recessed from a top portion of the upper structure and a second recess recessed from the first recess.

17. The semiconductor structure of claim 16, wherein both of the first recess and the second recess taper toward the substrate.

18. The semiconductor structure of claim 16, wherein an inner surface of the second recess is continuous with and aligned with a lateral surface of the periphery portion of the electrical pad.

19. The semiconductor structure of claim 16, wherein the upper structure includes a protrusion portion defining the first recess, wherein the protrusion portion tapers away from the substrate.

20. The semiconductor structure of claim 19, wherein the protrusion portion contacts the vertical transistor.
